(19) United States
(12) Patent Application Publication
(10) Pub. No.: US 2010/0208420 A1
(43) Pub. Date: Aug. 19, 2010

(54) ELECTRONIC DEVICE

(75) Inventors: Sheng-Chieh YANG, Taipei Hsien (TW); Cheng-Hung HSU, Taipei Hsien (TW); Xiao-Ping QIU, Taipei Hsien (TW); Chi-Wei KUO, Taipei Hsien (TW); Hsueh-Ping YANG, Taipei Hsien (TW); Chun-Hong KUO, Taipei Hsien (TW); Guo-Bao YE, Taipei Hsien (TW)

Correspondence Address: LADAS & PARRY LLP, 224 SOUTH MICHIGAN AVENUE, SUITE 1600, CHICAGO, IL, 60604, US

(73) Assignee: WISTRON CORPORATION, Taipei Hsien (TW)

(21) Appl. No.: 12/693,540

(22) Filed: Jan. 26, 2010

(30) Foreign Application Priority Data
Feb. 17, 2009 (TW) 098104972

(51) Int. Cl. H05K 7/00

(52) U.S. Cl. 361/679.01

(57) ABSTRACT

An electronic device includes a display body and a support base. The display body includes a bottom part, a first coupling member disposed on the bottom part, and a first positioning member disposed on the bottom part and located opposite to the first coupling member. The first coupling member is one of an engaging hook and an engaging hole. The support base is for supporting the display body, and includes a support face for supporting the bottom part, a second coupling member disposed on the support face, and a second positioning member disposed on the support face. The second coupling member is the other of the engaging hook and the engaging hole. The second positioning member is engaged with the first positioning member such that the second coupling member is positioned at a position of engagement with the first coupling member.

### CROSS-REFERENCE TO RELATED APPLICATION

This application claims priority of Taiwanese Application No. 098104972, filed on Feb. 17, 2009.

### BACKGROUND OF THE INVENTION

1. Field of the Invention

The invention relates to an electronic device, more particularly to an electronic device having a coupling structure disposed between a display body and a support base.

2. Description of the Related Art

In conventional electronic devices, such as liquid crystal televisions, liquid crystal displays, etc., a display body and a support base are generally coupled and secured through use of screws. However, use of screws not only takes up a lot of assembly time, there is also the additional cost for manufacturing the screws during the production process. Therefore, to devise a coupling structure for coupling together a display body and a support base so as to increase the speed of assembly to thereby reduce the assembly time during the product ion process, and so as to save manufacturing costs associated with use of fasteners, such as screws, is the subject of improvement of this invention.

### SUMMARY OF THE INVENTION

Therefore, a main object of this invention is to provide an electronic device that has a support base which can be coupled to a display body of the electronic device through screw-less coupling so as to save manufacturing costs associated with use of fasteners.

Another object of this invention is to provide an electronic device that can effectively increase the speed of assembling or disassembling a support base and a display body of the electronic device to thereby reduce assembly or disassembly time.

The aforesaid objects and solutions to the problems associated with the aforementioned prior art are realized using the technical means to be described hereinafter. An electronic device according to this invention comprises a display body and a support base.

The display body includes a bottom part, a first coupling member disposed on the bottom part and being one of an engaging hook and an engaging hole, and a first positioning member disposed on the bottom part and located opposite to the first coupling member. The support base is for supporting the display body, and includes a support face for supporting the bottom part, a second coupling member disposed on the support face and being the other of the engaging hook and the engaging hole, and a second positioning member disposed on the support face and engaged with the first positioning member such that the second coupling member is positioned at a position of engagement with the first coupling member.

In the aforesaid electronic device, the first positioning member has a horizontally extending resilient arm, and an engaging portion projecting from a bottom side of the resilient arm. The second positioning member is an engaging groove for engaging the engaging portion. The resilient arm defines a press portion operable to enable the engaging portion to disengage from the second positioning member.

In the aforesaid electronic device, the first positioning member is located rearwardly of the first coupling member. The resilient arm extends horizontally in a front-rear direction. The press portion is disposed rearwardly of the engaging portion and is accessible from a rear side of the display body.

In the aforesaid electronic device, the support face has a horizontal supporting face for abutting against the bottom part. The first coupling member is an engaging hole. The second coupling member is an inverted L-shaped engaging hook projecting from the supporting face. The engaging hook is extendible into the engaging hole to engage the bottom part. The second coupling member of the support base is engageable with the bottom part along an engagement direction parallel to the supporting face.

In the aforesaid electronic device, the bottom part has a horizontal force-bearing face for abutting against the support face. The second coupling member is an engaging hole. The first coupling member is an L-shaped engaging hook projecting from the force-bearing face. The engaging hook is extendible into the engaging hole to engage the support face. The first coupling member of the display body is engageable with the support face along an engagement direction parallel to the force-bearing face.

An electronic device according to this invention comprises a display body and a support base.

The display body includes a bottom part, two first coupling members disposed respectively on left and right sides of the bottom part, and a first positioning member disposed on the bottom part and located opposite to the first coupling members. Each of the first coupling members is one of an engaging hook and an engaging hole. The support base is for supporting the display body, and includes a support face for supporting the bottom part, two second coupling members disposed respectively on left and right sides of the support face, and a second positioning member disposed on the support face. Each of the second coupling members is the other of the engaging hook and the engaging hole. The second positioning member is engaged with the first positioning member such that each of the second coupling members is positioned at a position of engagement with a respective one of the first coupling members.

In the aforesaid electronic device, each of the first coupling members is an engaging hole. The support face has a horizontal supporting face for abutting against the bottom part. Each of the second coupling members is an engaging hook projecting from the supporting face. The engaging hook is extendible into the engaging hole to engage the bottom part.

In the aforesaid electronic device, the engaging hole is L-shaped, and has an alignment hole portion and an engaging hole portion formed at a front end of the alignment hole portion and having a width smaller than that of the alignment hole portion. The engaging hook has an inverted L-shaped hook body that is extendible into the alignment hole portion to engage the engaging hole portion. Each of the second coupling members of the support base is engageable with the bottom part and the engaging hole portion of a respective one of the first coupling members along an engagement direction parallel to the supporting face. The engaging hook further has a stop portion formed at a rear end of the hook body for abutting against the bottom part.

In the aforesaid electronic device, each of the second coupling members is an engaging hole. The bottom part has a horizontal force-bearing face for abutting against the support face. Each of the first coupling members is an engaging hook projecting from the force-bearing face. The engaging hook is extendible into the engaging hole to engage the support face.

In the aforesaid electronic device, the engaging hole is L-shaped, and has an alignment hole portion and an engaging hole portion formed at a rear end of the alignment hole portion and having a width smaller than that of the alignment hole portion. The engaging hook has an L-shaped hook body that is extendible into the alignment hole portion to engage the engaging hole portion. Each of the first coupling members of the display body is engageable with the support face and the engaging hole portion of a respective one of the second coupling members along an engagement direction parallel to the force-bearing face. The engaging hook further has a stop portion formed at a front end of the hook body for abutting against the support face.

In the electronic device of this invention, by virtue of the configurations of the first coupling member and the first positioning member of the display body, and the configurations of the second coupling member and the second positioning member of the support base, the support base can be quickly assembled to and positioned on the display body without requiring screws or can be quickly disassembled from the display body. Thus, the speed of assembly and disassembly can be increased to reduce assembly and disassembly time during the manufacturing process. In addition, manufacturing costs associated with fastening components, such as screws, nuts, etc., can be saved.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of the first preferred embodiment of an electronic device according to the present invention;

FIG. 2 is an exploded perspective view of the first preferred embodiment of an electronic device according to the present invention;

FIG. 3 is an exploded perspective view of the first preferred embodiment of an electronic device according to the present invention when viewed from another angle;

FIG. 4 is a bottom view of a display body of the first preferred embodiment of an electronic device according to the present invention;

FIG. 5 is a side view of a support base of the first preferred embodiment of an electronic device according to the present invention;

FIG. 6 is a front view of a support base of the first preferred embodiment of an electronic device according to the present invention;

FIG. 7 is a fragmentary sectional view of the first preferred embodiment of an electronic device according to the present invention, illustrating second coupling members of the support base extending into alignment hole portions of first coupling members of the display body;

FIG. 8 is a schematic assembled view of the first preferred embodiment of an electronic device according to the present invention, illustrating the second coupling members extending into the alignment hole portions of the first coupling members;

FIG. 9 is a fragmentary sectional view of the first preferred embodiment of an electronic device according to the present invention, illustrating how a support face of the support base urges a first positioning member upward so that a resilient arm of the first positioning member is displaced upward;

FIG. 10 is a fragmentary sectional view of the first preferred embodiment of an electronic device according to the present invention, illustrating how a limiting portion of the second coupling member of the support base engages a top side of a bottom part of the display body;

FIG. 11 is a schematic assembled view of the first preferred embodiment of an electronic device according to the present invention, illustrating how hook bodies of the second coupling members engage the engaging hole portions of the first coupling members, and how stop portions of the second coupling members abut against inner wall surfaces of the bottom part;

FIG. 12 is a fragmentary sectional view of the first preferred embodiment of an electronic device according to the present invention, illustrating how an engaging portion of the first positioning member engages the second positioning member of the support base;

FIG. 13 is a fragmentary sectional view of the first preferred embodiment of an electronic device according to the present invention, illustrating a press portion when pressed upward to enable the engaging portion of the first positioning member to disengage from the second positioning member;

FIG. 14 is an exploded rear view of the second preferred embodiment of an electronic device according to the present invention;

FIG. 15 is a top view of a support base of the second preferred embodiment of an electronic device according to the present invention;

FIG. 16 is a fragmentary sectional view of the second preferred embodiment of an electronic device according to the present invention, illustrating first coupling members of the display body extending into alignment hole portions of second coupling members of the support base;

FIG. 17 is a fragmentary sectional view of the second preferred embodiment of an electronic device according to the present invention, illustrating how limiting portions of the first coupling members of the display body engage a bottom side of a support face of the support base;

FIG. 18 is an exploded perspective view of the third preferred embodiment of an electronic device according to the present invention;

FIG. 19 is an exploded perspective view of the third preferred embodiment of an electronic device according to the present invention when viewed from another angle;

FIG. 20 is a fragmentary sectional view of the third preferred embodiment of an electronic device according to the present invention, illustrating how a limiting portion of a second coupling member of a support base engages a top side of a bottom part of a display body;

FIG. 21 is an exploded perspective view of the fourth preferred embodiment of an electronic device according to the present invention;

FIG. 22 is an exploded perspective view of the fourth preferred embodiment of an electronic device according to the present invention when viewed from another angle; and

FIG. 23 is a fragmentary sectional view of the fourth preferred embodiment of an electronic device according to the present invention, illustrating how a limiting portion of a first coupling member of a display body engages a bottom side of a support face of a support base.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

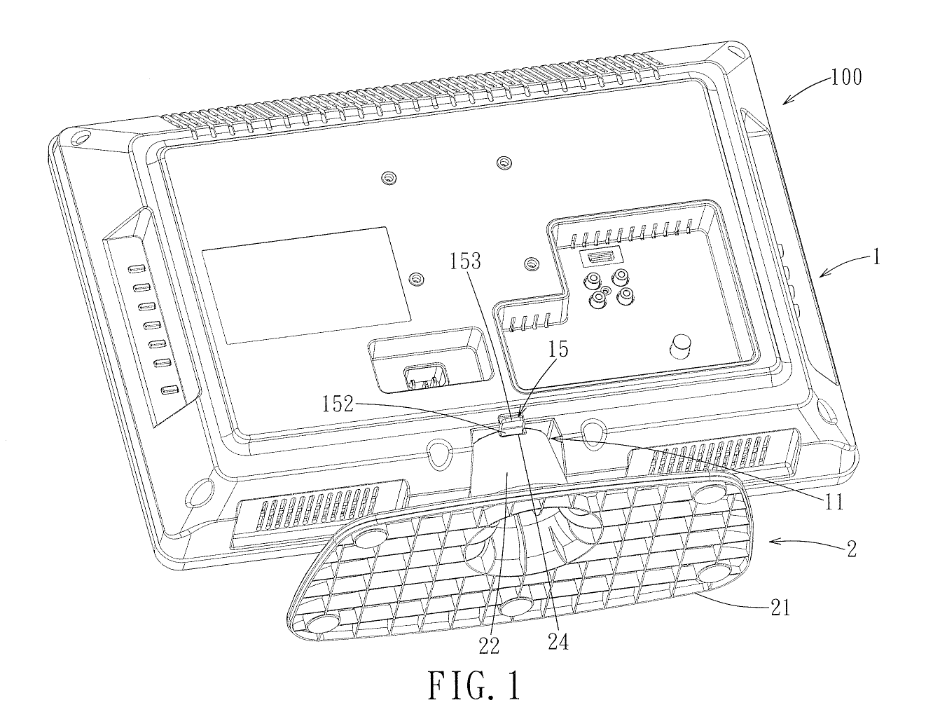

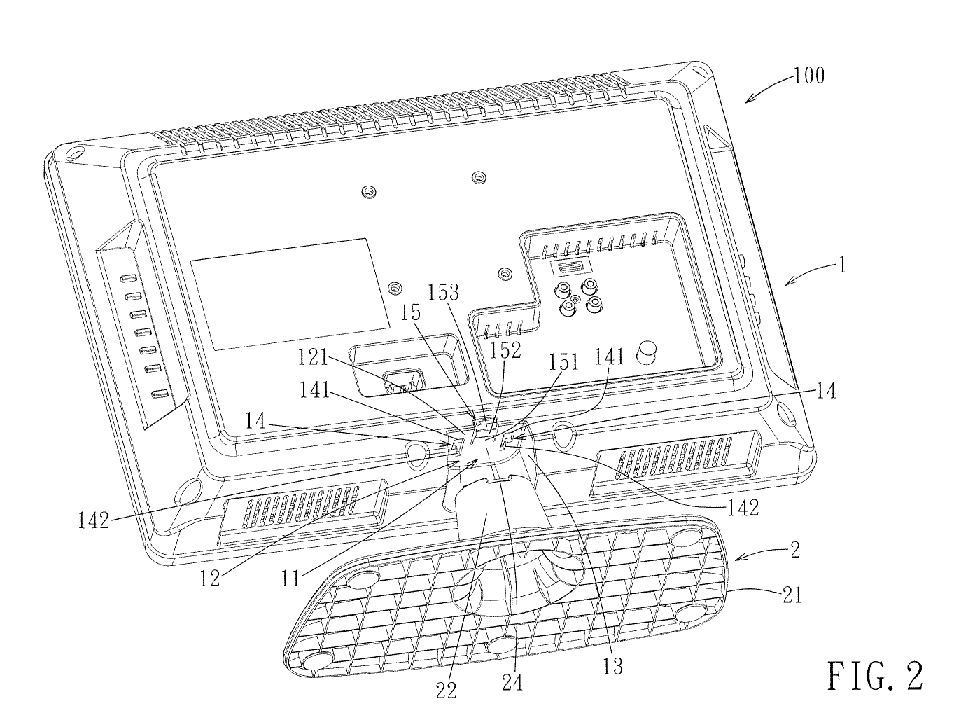

Referring to FIGS. 1 and 2, the first preferred embodiment of an electronic device 100 according to the present invention is exemplified as a liquid crystal television and includes a display body 1 and a support base 2 for supporting the display body 1. In practice, the electronic device 100 may be a plasma television, a liquid crystal display, etc.

As shown in FIGS. 2, 3 and 4, the display body 1 includes a groove 11 which is provided in a bottom portion thereof for mounting the support base 2, and which has an opening oriented downwardly and rearwardly. The display body 1 has a bottom part 12, and a peripheral wall 13 formed at a periphery of the bottom part 12 and cooperating therewith to define the groove 11. The bottom part 12 has a substantially horizontal force-bearing face 121 for contacting the support base 2. The display body 1 further includes two first coupling members 14 disposed respectively on left and right sides of the bottom part 12, and a first positioning member 15 disposed on the bottom part 12 rearwardly of the first coupling members 14. In this embodiment, each of the first coupling members 14 is an L-shaped engaging hole, and has an alignment hole portion 141 and an engaging hole portion 142 formed at a front end of the alignment hole portion 141 and having a width (from left to right) smaller than that of the alignment hole portion 141. The engaging hole portions 142 of the first coupling members 14 are respectively connected to the alignment hole portions 141 at where the alignment hole portions 141 are close to each other. The first positioning member 15 has a resilient arm 151 extending horizontally in a front-rear direction and partly disposed rearwardly of the alignment hole portions 141 of the first coupling members 14, and an engaging portion 152 projecting from a middle section of a bottom side of the resilient arm 151.

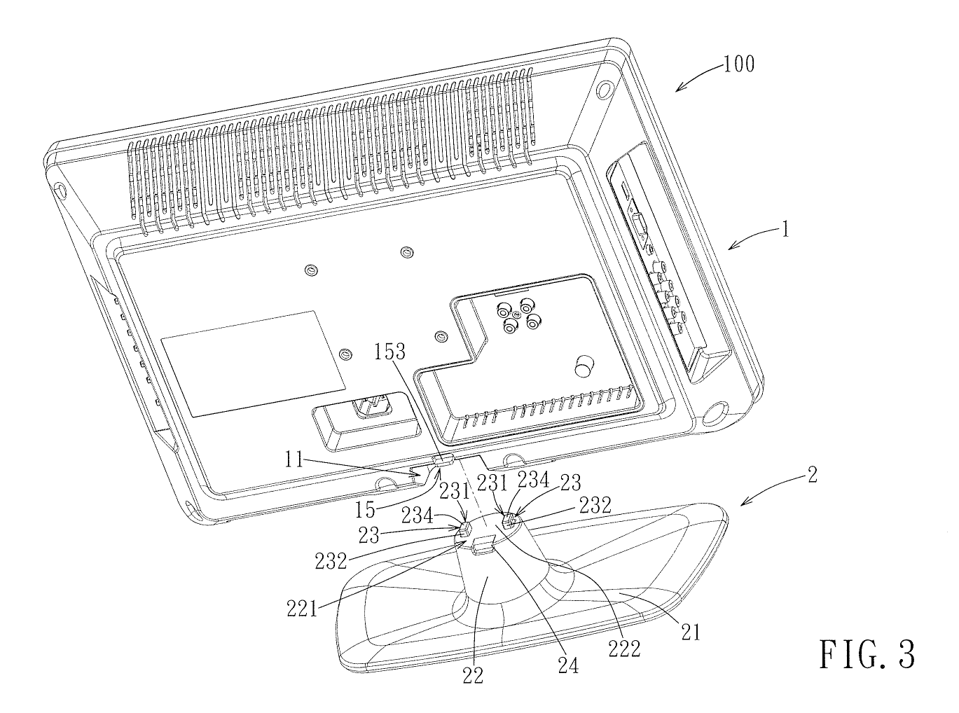

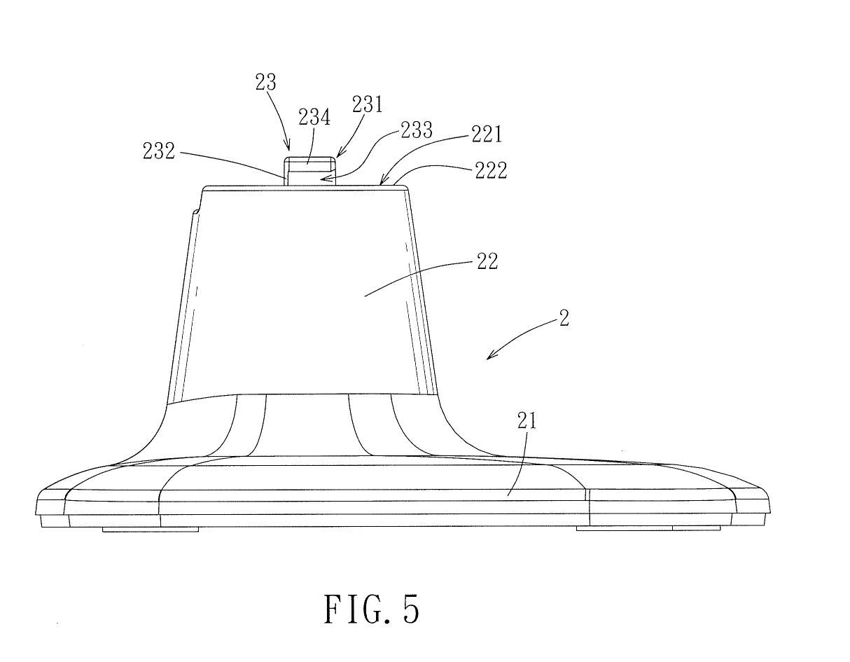

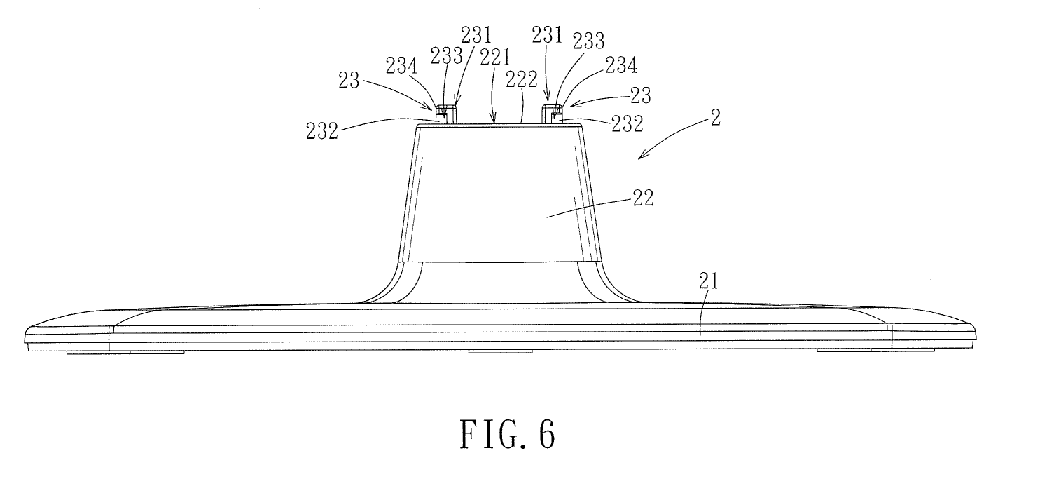

As shown in FIGS. 3, 4, 5 and 6, the support base 2 includes a plate body 21 for standing on a flat surface (not shown), a post 22 projecting from a top surface of the plate body 21 to be received in the groove 11 in the display body 1 and having a support face 221, and two second coupling members 23. The second coupling members 23 are disposed respectively on left and right sides of the support face 221 of the post 22. The support face 221 has a horizontal supporting face 222 for abutting against the force-bearing face 121 of the bottom part 12. In this embodiment, each of the second coupling members 23 is an engaging hook projecting from the supporting face 222 for engaging a respective one of the first coupling members 14. Each of the second coupling members 23 has an inverted L-shaped hook body 231, and a stop portion 232 formed at a rear end of the hook body 231. The hook body 231 and the stop portion 232 cooperatively define an engaging space 233 having an opening that opens forwardly and outwardly. Thus, the second coupling members 23 can be respectively extended into the alignment hole portions 141 of the first coupling members 14, and then moved forwardly a certain distance such that the hook bodies 231 engage the engaging hole portions 142 and the bottom part 12 with the stop portions 232 abutting against the bottom part 12 of the display body 1 to limit the distance over which the second coupling members 23 are movable. In addition, the support base 2 further includes a second positioning member 24 disposed on a rear end edge of the support face 221 of the post 22. The second positioning member 24 is an engaging groove for engagement with the engaging portion 152 of the first positioning member 15. Thus, the second coupling members 23 can be positioned at the position of engagement with the first coupling members 14 so that the support base 2 can be assembled securely to and positioned on the display body 1.

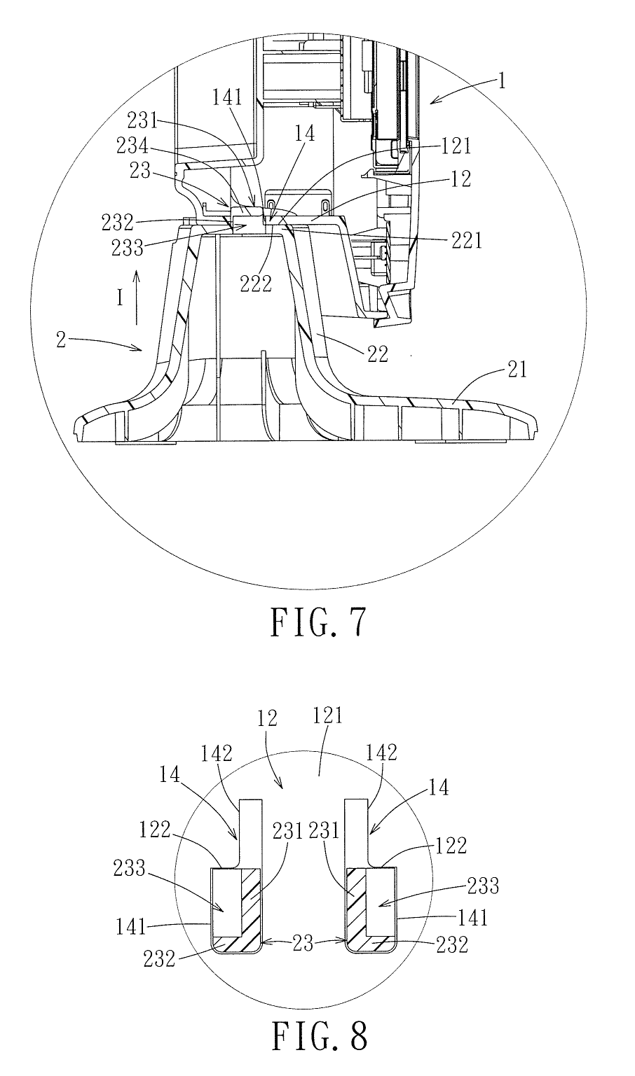

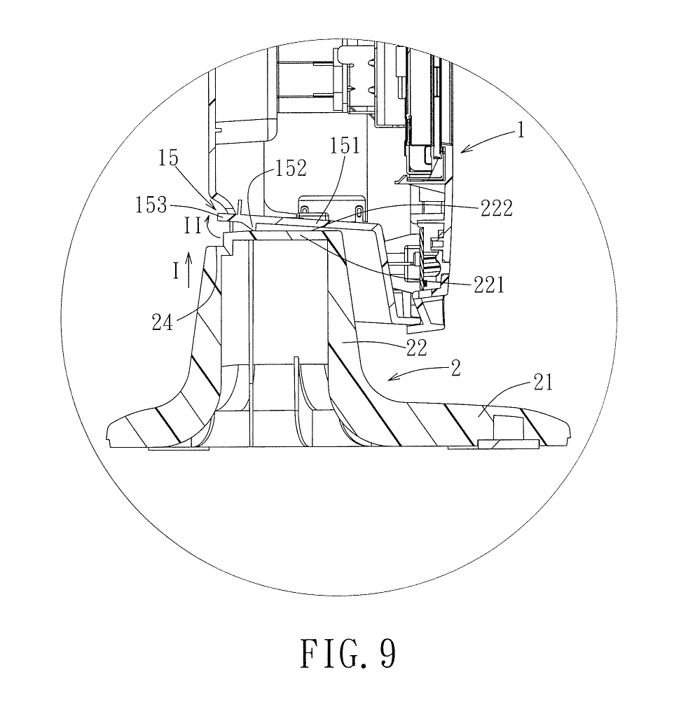

Referring to FIGS. 7, 8 and 9, when it is desired to assemble the support base 2 to the display body 1, the two second coupling members 23 of the support base 2 are first aligned with the alignment hole portions 141 of the first coupling members 14 of the display body 1. Subsequently, the support base 2 is moved upward in a direction indicated by arrow (I) so that the second coupling members 23 respectively extend into the alignment hole portions 141 of the first coupling members 14. When the supporting face 222 of the support face 221 of the post 22 abuts against the engaging portion 152 of the first positioning member 15, the post 22 will exert an upward force on the resilient arm 151 of the first positioning member 15 to cause the resilient arm 151 to move upward in a direction as indicated by arrow (II) until the supporting face 222 of the support face 221 of the post 22 abuts against the force-bearing face 121 of the bottom part 12 of the display body 1, at which point the support base 2 cannot be moved upward any further.

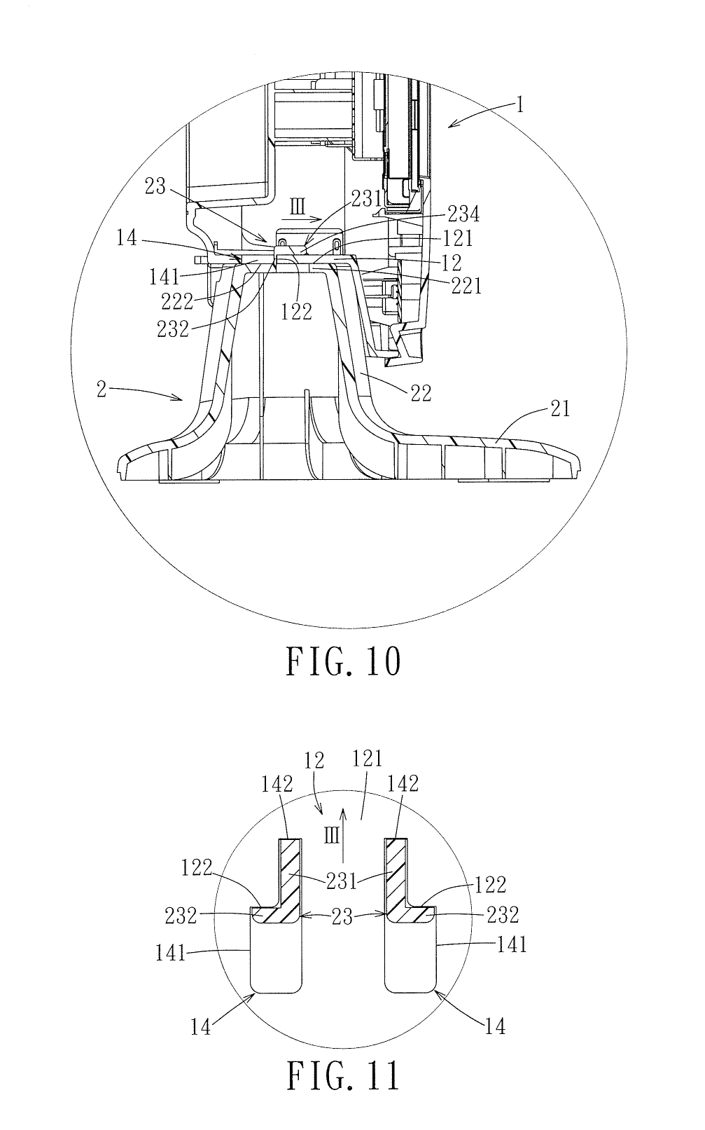

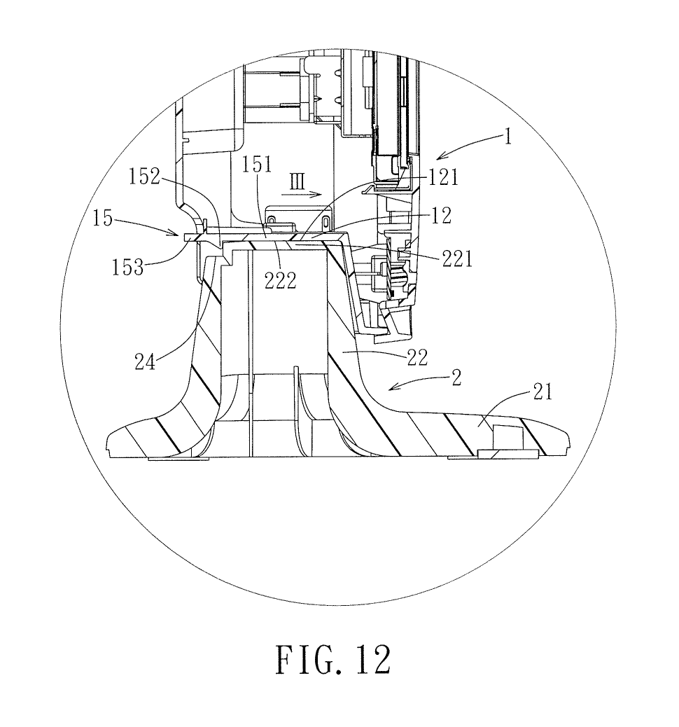

Referring to FIGS. 10, 11 and 12, the support base is subsequently moved a certain distance in an engagement direction as indicated by arrow (III), which is parallel to the supporting face 222, such that part of the bottom part 12 is moved into the engaging spaces 233 (shown in FIG. 7) respectively defined by the second coupling members 23. When the stop portions 232 of the second coupling members 23 respectively abut against inner wall surfaces 122 of the bottom part 12 that respectively define the first coupling members 14, the support base 2 cannot be moved forwardly relative to the display body 1 any further. At this time, the hook body 231 of each of the second coupling members 23 is engaged with the engaging hole portion 142 of the respective one of the first coupling members 14, and a limiting portion 234 at a top end of the hook body 231 is engaged with a top side of the bottom part 12, while the second positioning member 24 of the post 22 is moved to the position of the engaging portion 152 of the first positioning member 15 such that, by virtue of the restoring force of the resilient arm 151 of the first positioning member 15, the engaging portion 152 can be engaged with the second positioning member 24. By virtue of the engagement of the second coupling members 23 with the first coupling members 14 and the bottom part 12, and by virtue of the engagement between the engaging portion 152 of the first positioning member 15 with the second positioning member 24, the support base 2 can be assembled firmly to and secured on the display body 1 and can be guarded against movement relative to the display body 1. Thus, the supporting face 222 of the support face 221 can provide the force-bearing face 121 of the bottom part 12 with a supporting force in an upward direction which is perpendicular to the engagement direction so as to support the display body 1 on the flat surface.

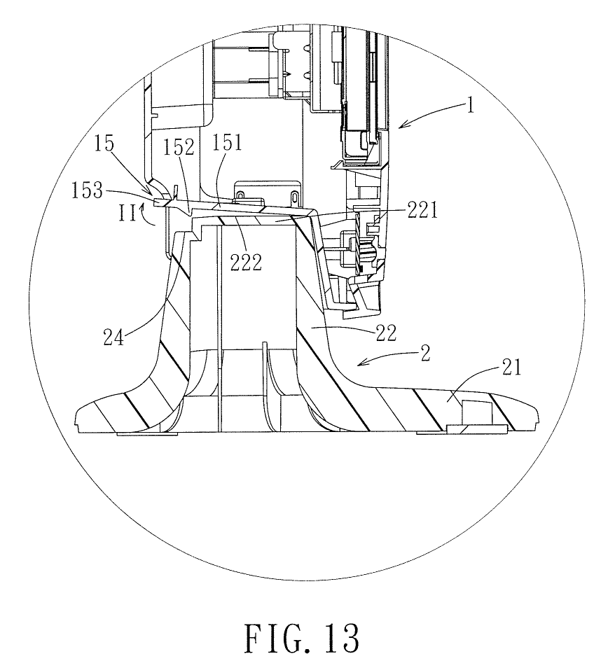

Referring to FIG. 13, when it is desired to remove the support base 2 from the display body 1, a press portion 153 defined by the resilient arm 151, disposed rearwardly of the engaging portion 152, and accessible from a rear side of the display body 1 is pressed upward such that the resilient arm 151 is displaced upward in a direction indicated by arrow (II) to enable the engaging portion 152 to be disengaged from the second positioning member 24 of the post 22. Subsequently, the support base 2 can be moved in a direction opposite to the direction indicated by arrow (III) (shown in FIG. 10) so that the hook bodies 231 of the second coupling members 23 are respectively disengaged from the engaging hole portions 142 of the first coupling members 14 and the bottom part 12, as shown in FIG. 8, and are respectively moved to the positions of the alignment hole portions 141. Thereafter, the support base 2 can be pulled downward in a direction opposite to the direction indicated by the arrow (I) (shown in FIG. 7) so that the second coupling members 23 of the support base 2 are disengaged from the alignment hole portions 141 of the first coupling members 14. Detachment of the support base 2 from the display body 1 is thus completed. It should be noted that the configuration of the resilient arm 151 of the first positioning member 15 to extend horizontally in the front-rear direction of the first positioning member 15 enables the press portion 153 of the resilient arm 151 to be accessible from the rear side of the display body 1 so that an operator can quickly and conveniently separate the support base 2 from the display body 1.

Due to the configurations of the first coupling members 14 and the first positioning member 15 of the display body 1, and the configurations of the second coupling members 23 and the second positioning member 24 of the support base 2, the support base 2 can be quickly assembled to and positioned on the display body 1 without using screw fasteners, or can be detached conveniently from the display body 1. Thus, the speed of assembly or disassembly can be increased to reduce the working time associated with assembly or disassembly of the electronic device 100 during the manufacturing process. Moreover, the cost associated with use of fasteners, such as screws or nuts, can be saved. It is noted that, while the first and second positioning members 15, 24 may be dispensed with in design so that the display body 1 and the support base 2 are coupled only through the first coupling members 14 and the second coupling members 23, the arrangement of the first and second positioning members 15, 24 as disclosed in this embodiment can enhance the strength of coupling between the display body 1 and the support base 2 and prevent relative sliding movement between the display body 1 and the support base 2 due to external forces.

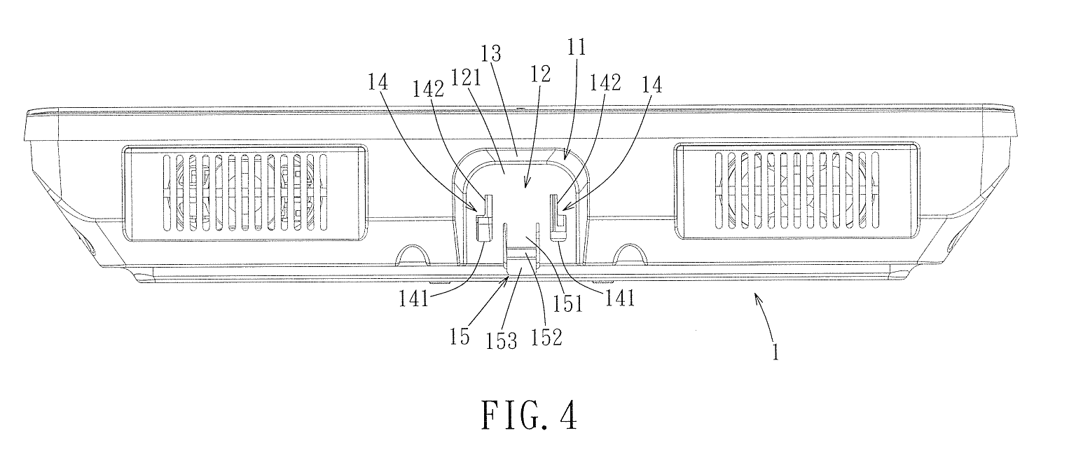

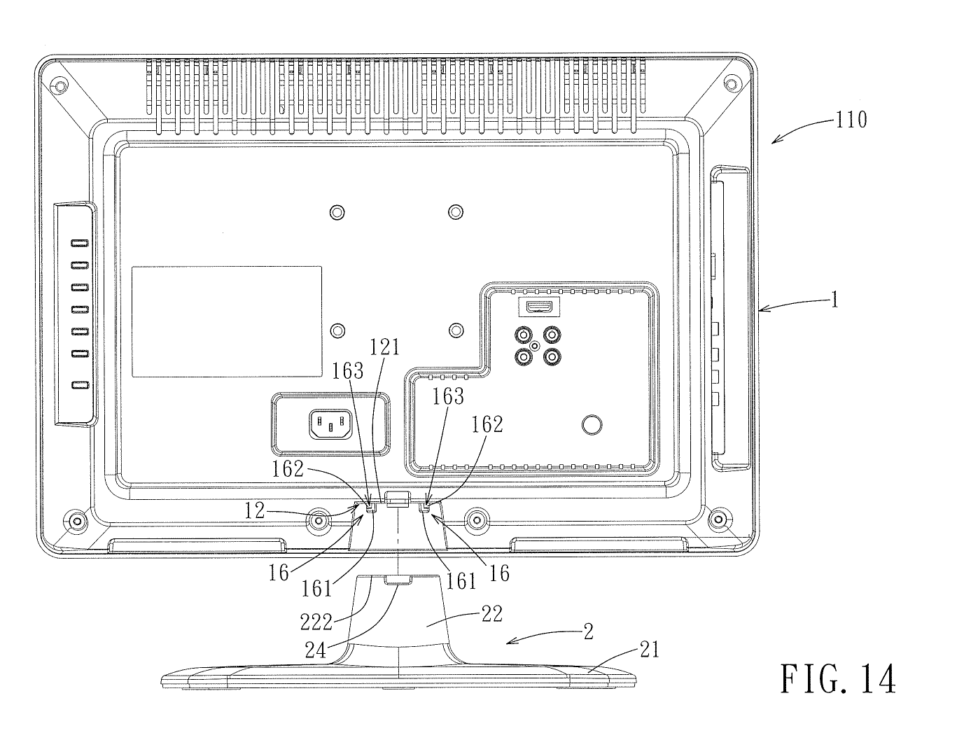

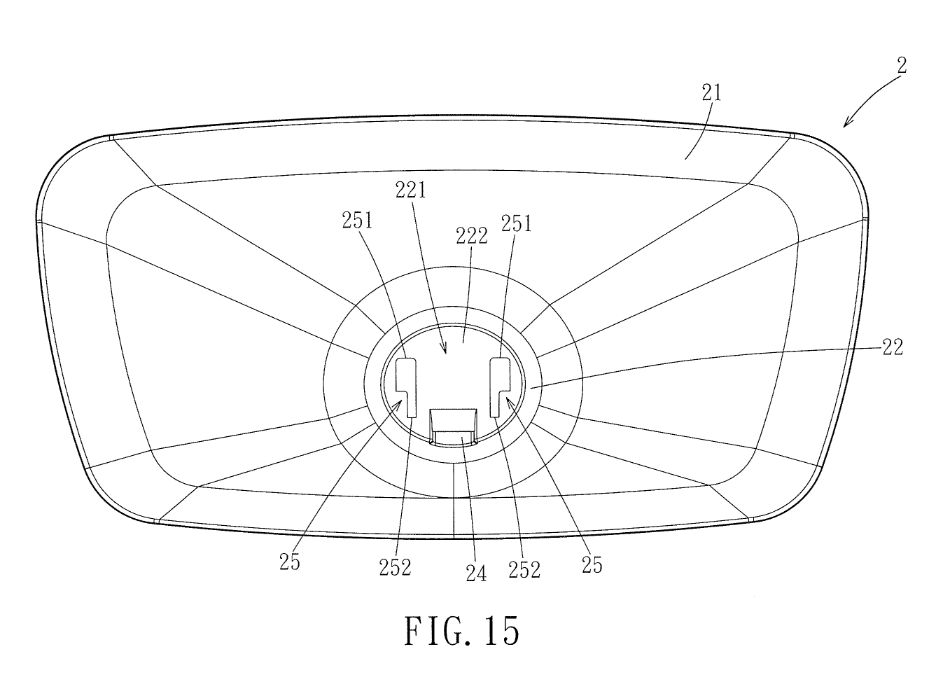

Referring to FIGS. 14 and 15, the second preferred embodiment of an electronic device 110 according to this invention is generally identical to the first preferred embodiment in structure. The difference resides in that each of the first coupling members 16 of the display body 1 of this embodiment is an engaging hook projecting from the force-bearing face 121 of the bottom part 12, and has a structure identical to that of the second coupling members 23 (as shown in FIG. 3), and each of the second coupling members 25 of the support base 2 of this embodiment is an L-shaped engaging hole provided in the support face 221, and has a structure identical to that of the first coupling members 14 (as shown in FIG. 4).

Each of the first coupling members 16 has an L-shaped hook body 161, and a stop portion 162 formed at a front end of the hook body 161. The hook body 161 and the stop portion 162 cooperatively define an engaging space 163 having an opening that opens rearwardly and outwardly. Each of the second coupling members 25 has an alignment hole portion 251, and an engaging hole portion 252 formed at a rear end of the alignment hole portion 251 and having a width (from left to right) smaller than that of the alignment hole portion 251. The engaging hole portions 252 of the second coupling members 25 are respectively connected to the alignment hole portions 251 at where the alignment hole portions 251 are close to each other.

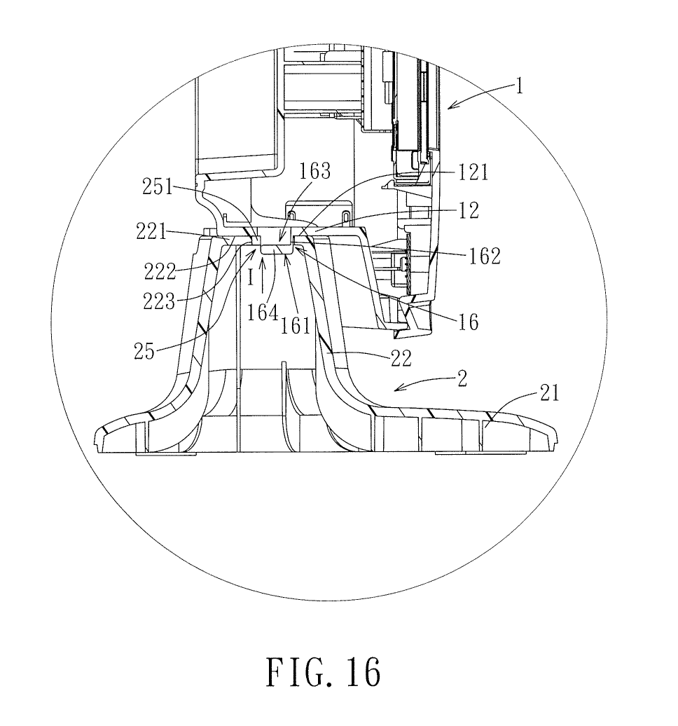

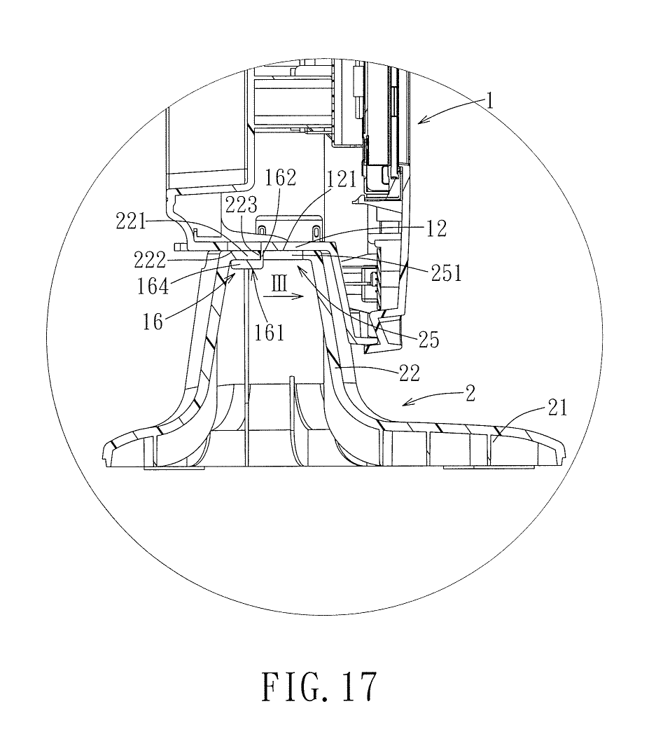

Referring to FIGS. 14, 16 and 17, when it is desired to assemble the support base 2 to the display body 1, the alignment hole portions 251 of the second coupling members 25 of the support base 2 are first aligned with the first coupling members 16 of the display body 1, and the support base 2 is then moved upward in a direction indicated by arrow (I) so that the first coupling members 16 respectively extend into the alignment hole portions 251 of the second coupling members 25. When the supporting face 222 of the support face 221 of the post 22 abuts against the force-bearing face 121 of the bottom part 12 of the display body 1, the support base 2 cannot be moved upward any further. Subsequently, the support base 2 is moved forward a certain distance in a direction indicated by arrow (III), or the display body 1 is moved rearward a certain distance in an engagement direction opposite to the direction indicated by arrow (III) and parallel to the force-bearing face 121 such that part of the support face 221 is moved into the engaging spaces 163 defined by the first coupling members 16. When the stop portions 162 of the first coupling members 16 respectively abut against inner wall surfaces 223 of the support face 221 which define the second coupling members 25, the support base 2 cannot be moved forward relative to the display body 1 any further. At this time, the hook body 161 of each of the first coupling members 16 is engaged with the engaging hole portion 252 of the respective one of the second coupling members 25 (as shown in FIG. 15), and a limiting portion 164 at a bottom end of the hook body 161 is engaged with a bottom side of the support face 221.

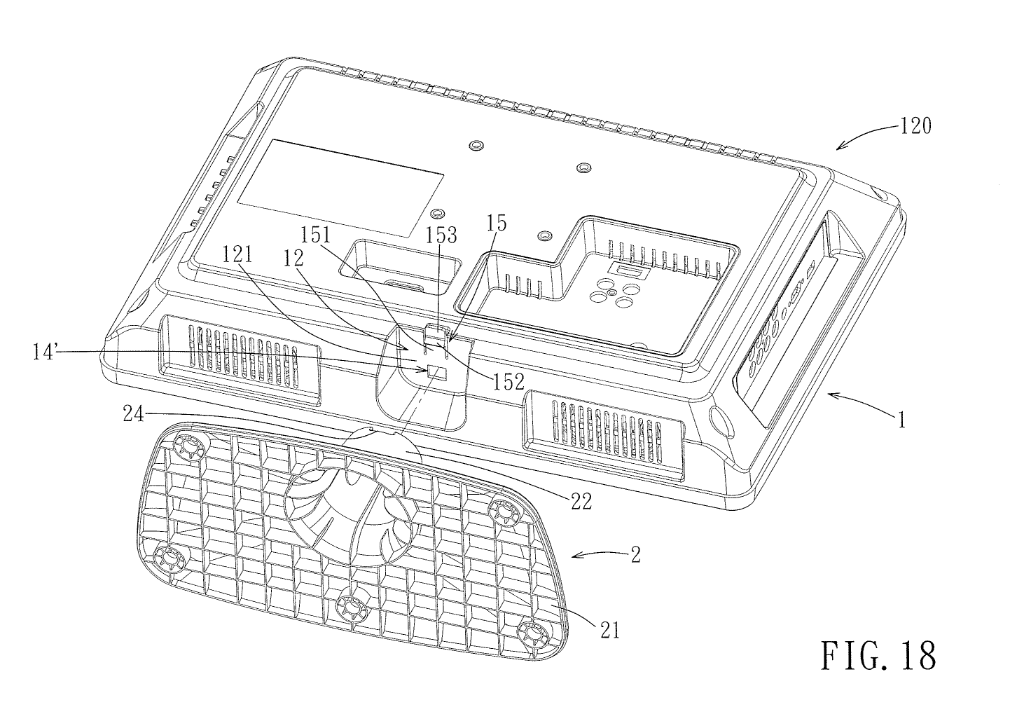

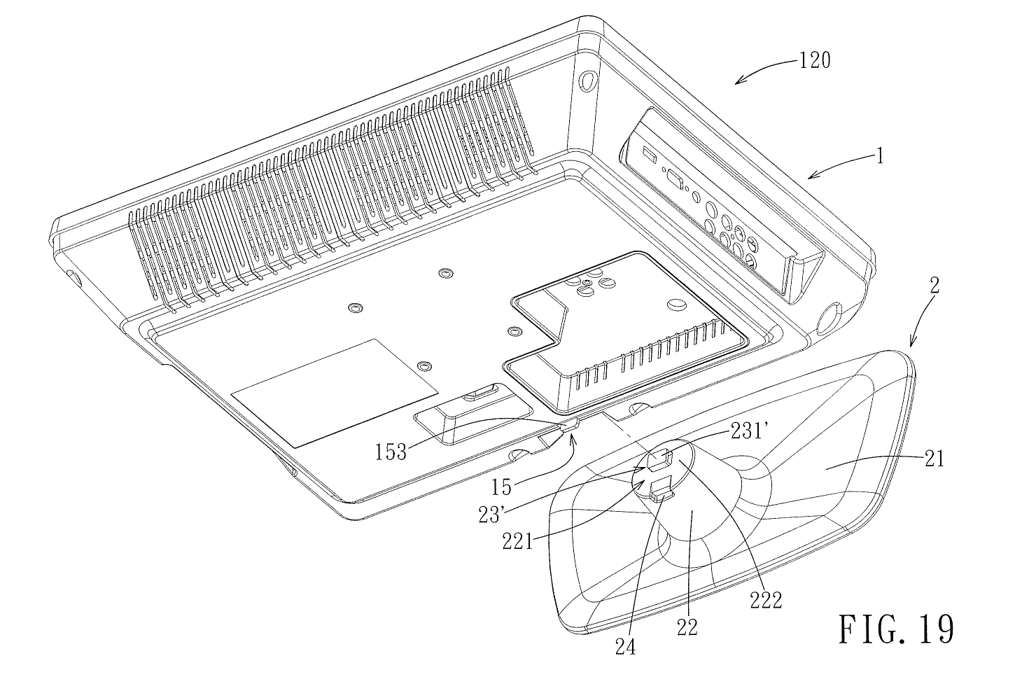

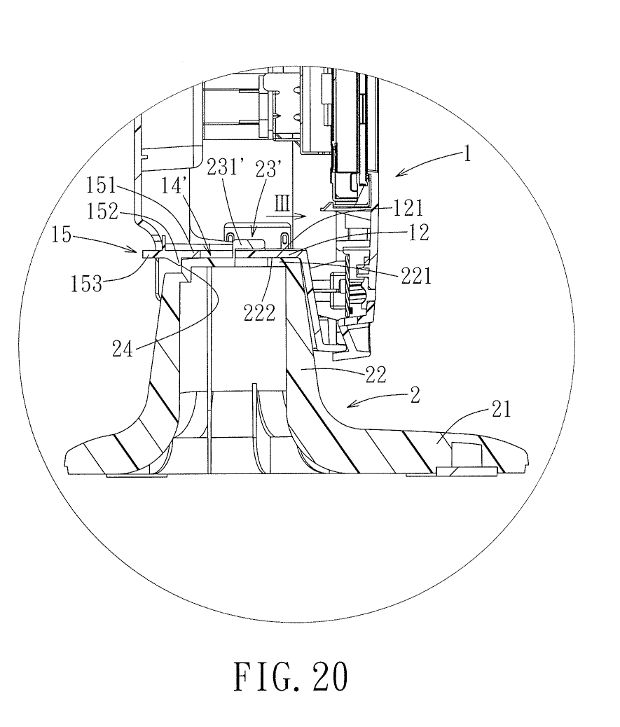

Referring to FIGS. 18, 19 and 20, the third preferred embodiment of an electronic device 120 according to this invention is generally identical to the first preferred embodiment in structure. The difference resides in that, in this embodiment, the first coupling member 14′ of the display body 1 is a rectangular engaging hole disposed in front of the first positioning member 15, and the second coupling member 23′ of the support base 2 is an inverted L-shaped engaging hook projecting from the supporting face 222 of the support face 221 and is disposed in front of the second positioning member 24. When it is desired to assemble the support base 2 to the display body 1, the support base 2 is first moved upward so that the second coupling member 23′ extends into the first coupling member 14′, and is then moved forward in an engagement direction indicated by arrow (III) such that the second coupling member 23′ engages the first coupling member 14′, a limiting portion 231′ of the second coupling member 23′ engages the top side of the bottom part 12 of the display body 1, and the engaging portion 152 of the first positioning member 15 engages the second positioning member 24 of the post 22.

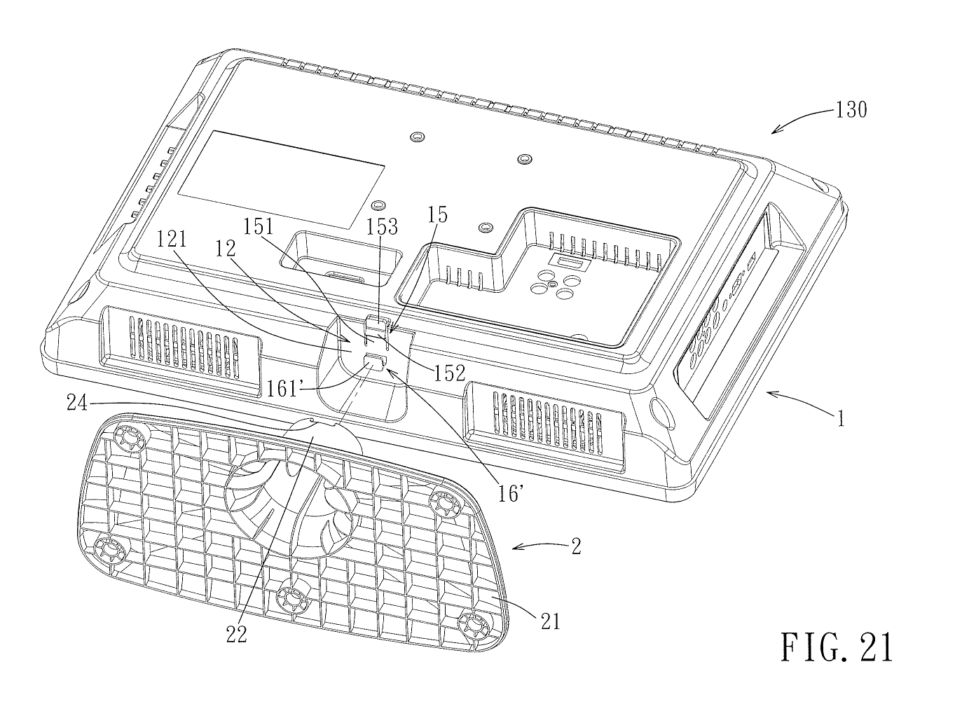

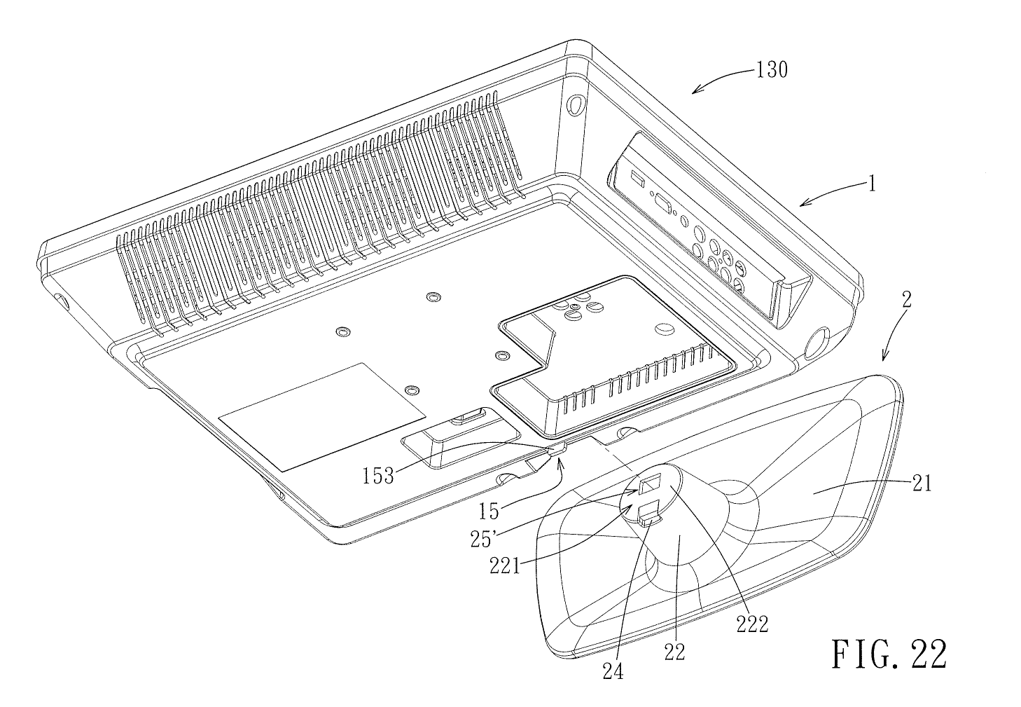

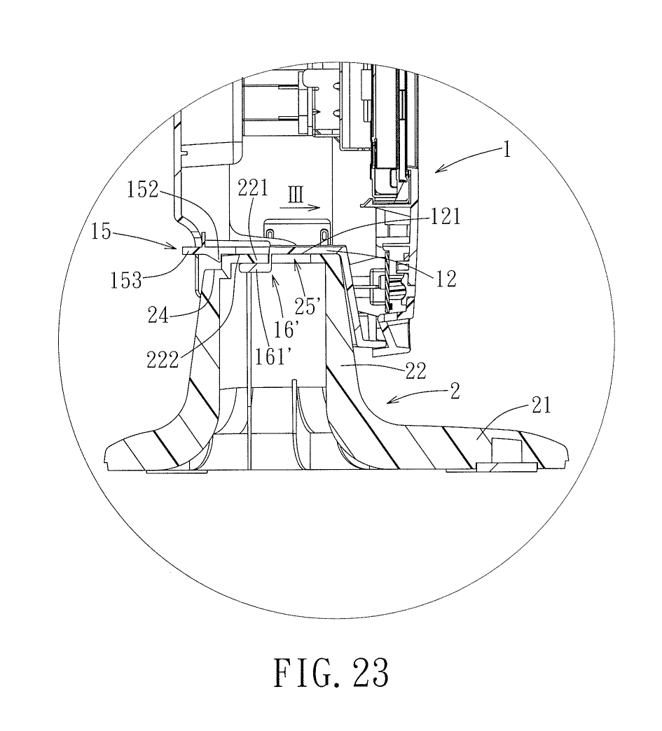

Referring to FIGS. 21, 22 and 23, the fourth preferred embodiment of an electronic device 130 according to this invention is generally identical to the third preferred embodiment in structure. The difference resides in that, in this embodiment, the first coupling member 16′ of the display body 1 is an L-shaped engaging hook projecting from the force-bearing face 121 of the bottom part 12 and disposed in front of the first positioning member 15, and the second coupling member 25′ of the support base 2 is a rectangular engaging hole disposed in front of the second positioning member 24. When it is desired to assemble the support base 2 to the display body 1, the support base 2 is first moved upward so that the first coupling member 16′ extends into the second coupling member 25′, and is then moved forward in a direction indicated by arrow (III), or the display body 1 is moved rearward a certain distance in an engagement direction opposite to that indicated by arrow (III) such that the first coupling member 16′ engages the second coupling member 25′, a limiting portion 161′ of the first coupling member 16′ engages the bottom side of the support face 221 of the post 22 of the support base 2, and the engaging portion 152 of the first positioning member 15 engages the second positioning member 24 of the post 22.

In summary, in the electronic device 100, 110, 120, 130 of this invention, due to the configurations of the first coupling member(s) 14, 14′, 16, 16′ and the first positioning member 15 of the display body 1, and the configurations of the second coupling member (s) 23, 23′, 25, 25′ and the second positioning member 24 of the support base 2, the support base 2 can be quickly assembled to and positioned on the display body 1 without using screw fasteners, or can be conveniently separated from the display body 1. Thus, the speed of assembly or disassembly can be increased to reduce the working time associated with assembly or disassembly of the electronic device 100, 110, 120, 130 during the manufacturing process. Moreover, the cost associated with use of fasteners, such as screws or nuts, can be saved.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An electronic device comprising:
a display body including
a bottom part,
a first coupling member disposed on said bottom part,
a first positioning member disposed on said bottom part and located opposite to said first coupling member; and
a support base for supporting said display body, and including
a support face for supporting said bottom part,
a second coupling member disposed on said support face, and
a second positioning member disposed on said support face and engaged with said first positioning member such that said second coupling member is positioned at a position of engagement with said first coupling member.

2. The electronic device of claim 1, wherein said first coupling member is one of an engaging hook and an engaging hole, and said second coupling member is the other of said engaging hook and said engaging hole.

3. The electronic device of claim 1, wherein said first positioning member has a horizontally extending resilient arm, and an engaging portion projecting from a bottom side of said resilient arm, said second positioning member being an engaging groove for engaging said engaging portion.

4. The electronic device of claim 3, wherein said resilient arm defines a press portion operable to enable said engaging portion to disengage from said second positioning member.

5. The electronic device of claim 4, wherein said first positioning member is located rearwardly of said first coupling member, said resilient arm extending horizontally in a front-rear direction, said press portion being disposed rearwardly of said engaging portion and being accessible from a rear side of said display body.

6. The electronic device of claim 1, wherein said support face has a horizontal supporting face for abutting against said bottom part, said first coupling member being an engaging hole, said second coupling member being an inverted L-shaped engaging hook projecting from said supporting face, said engaging hook being extendible into said engaging hole to engage said bottom part.

7. The electronic device of claim 6, wherein said second coupling member of said support base is engageable with said bottom part along an engagement direction parallel to said supporting face.

8. The electronic device of claim 1, wherein said bottom part has a horizontal force-bearing face for abutting against said support face, said second coupling member being an engaging hole, said first coupling member being an L-shaped engaging hook projecting from said force-bearing face, said engaging hook being extendible into said engaging hole to engage said support face.

9. The electronic device of claim 8, wherein said first coupling member of said display body is engageable with said support face along an engagement direction parallel to said force-bearing face.

10. An electronic device comprising:
a display body including
a bottom part,
two first coupling members disposed respectively on left and right sides of said bottom part, each of said first coupling members being one of an engaging hook and an engaging hole, and
a first positioning member disposed on said bottom part and located opposite to said first coupling members; and
a support base for supporting said display body, and including
a support face for supporting said bottom part,
two second coupling members disposed respectively on left and right sides of said support face, each of said second coupling members being the other of said engaging hook and said engaging hole, and
a second positioning member disposed on said support face and engaged with said first positioning member such that each of said second coupling members is positioned at a position of engagement with a respective one of said first coupling members.

11. The electronic device of claim 10, wherein said first positioning member has a horizontally extending resilient arm, and an engaging portion projecting from a bottom side of said resilient arm, said second positioning member being an engaging groove for engaging said engaging portion.

12. The electronic device of claim 11, wherein said resilient arm defines a press portion operable to enable said engaging portion to disengage from said second positioning member.

13. The electronic device of claim 12, wherein said first positioning member is located rearwardly of said first coupling members, said resilient arm extending horizontally in a front-rear direction, said press portion being disposed rearwardly of said engaging portion and being accessible from a rear side of said display body.

14. The electronic device of claim 10, wherein each of said first coupling members is an engaging hole, said support face having a horizontal supporting face for abutting against said bottom part, each of said second coupling members being an engaging hook projecting from said supporting face, said engaging hook being extendible into said engaging hole to engage said bottom part.

15. The electronic device of claim 14, wherein said engaging hole is L-shaped, and has an alignment hole portion and an engaging hole portion formed at a front end of said alignment hole portion and having a width smaller than that of said alignment hole portion, said engaging hook having an inverted L-shaped hook body that is extendible into said alignment hole portion to engage said engaging hole portion, each of said second coupling members of said support base being engageable with said bottom part and said engaging hole portion of a respective one of said first coupling members along an engagement direction parallel to said supporting face.

16. The electronic device of claim 15, wherein said engaging hook further has a stop portion formed at a rear end of said hook body for abutting against said bottom part.

17. The electronic device of claim 16, wherein said first positioning member has a horizontally extending resilient arm, and an engaging portion projecting from a bottom side of said resilient arm, said second positioning member being an engaging groove for engaging said engaging portion, said resilient arm defining a press portion operable to enable said engaging portion to disengage from said second positioning member.

18. The electronic device of claim 10, wherein each of said second coupling members is an engaging hole, said bottom part having a horizontal force-bearing face for abutting against said support face, each of said first coupling members being an engaging hook projecting from said force-bearing face, said engaging hook being extendible into said engaging hole to engage said support face.

19. The electronic device of claim 18, wherein said engaging hole is L-shaped, and has an alignment hole portion and an engaging hole portion formed at a rear end of said alignment hole portion and having a width smaller than that of said alignment hole portion, said engaging hook having an L-shaped hook body that is extendible into said alignment hole portion to engage said engaging hole portion, each of said first coupling members of said display body being engageable with said support face and said engaging hole portion of a respective one of said second coupling members along an engagement direction parallel to said force-bearing face.

20. The electronic device of claim 19, wherein said engaging hook further has a stop portion formed at a front end of said hook body for abutting against said support face.

21. The electronic device of claim 20, wherein said first positioning member has a horizontally extending resilient arm, and an engaging portion projecting from a bottom side of said resilient arm, said second positioning member being an engaging groove for engaging said engaging portion, said resilient arm defining a press portion operable to enable said engaging portion to disengage from said second positioning member.
